(19) United States
(12) Patent Application Publication
(10) Pub. No.: US 2025/0194015 A1
(43) Pub. Date: Jun. 12, 2025

(54) A PACKAGING ARRANGEMENT FOR A QUANTUM PROCESSOR

(71) Applicant: SCALINQ AB, Göteborg (SE)

(72) Inventors: Robert REHAMMAR, Romelanda (SE); Giovanna TANCREDI, Göteborg (SE); Lars JÖNSSON, Olofstorp (SE); Sandoko KOSEN, Mölndal (SE)

(21) Appl. No.: 18/845,752

(22) PCT Filed: Feb. 28, 2023
(86) PCT No.: PCT/EP2023/054914

§ 371 Date: Sep. 10, 2024

(30) Foreign Application Priority Data
Mar. 10, 2022 (SE) 2230067-7

(51) Int. Cl. H05K 1/18; G06N 10/40; H05K 3/30; H10N 60/81; H10N 69/00

(52) U.S. Cl. CPC H05K 1/181; G06N 10/40; H05K 3/303; H10N 60/81; H10N 69/00

(57) ABSTRACT

A packaging arrangement (100) for a quantum processor chip (101) comprising a PCB attachment plate (120) of a conductive material. The PCB attachment plate is arranged to receive a printed circuit board, PCB, (110) in a stacked configuration where the PCB faces a first surface of the PCB attachment plate. The PCB attachment plate (120) comprises an attachment plate cavity (121) on the first surface, and comprises a ridge (122) arranged at least partly surrounding the attachment plate cavity and arranged protruding from the first surface. wherein the ridge is arranged to receive the quantum processor chip (101).

### TECHNICAL FIELD

The present disclosure relates to packaging arrangements for superconducting-based circuits such as quantum processors, where the packaging arrangement is arranged to distribute operation signals to the quantum processor and preferably facilitate arranging the quantum processor in desired operating conditions.

### BACKGROUND

A quantum processor is normally a silicon-or sapphire-based integrated circuit, i.e., chip, which is cooled to be superconducting. The quantum processor has a number of quantum bits (qubits) that, similarly to bits in a classical computer, store information. The qubits are normally interconnected and controlled by control signals in the microwave domain to perform quantum computations. A control signal may be a pulse of some frequency resulting in a change in quantum state of a qubit, i.e., a resonance frequency of the qubit, which normally is within 1-10 GHz. Each qubit typically requires on average three separate control signals with respective signal paths to perform computations with the quantum processor. For example, a quantum processor with 25 qubits may require around 75 control signals with respective signal paths.

The quantum processor is typically arranged in a cryostat where the temperature at the processor is around 10 millikelvin. The control signals are typically transmitted and received by microwave equipment/instrumentation at room temperature. The cryostat therefore often comprise several chambers where the temperature is decreased in steps from the room temperature. The control signals are arranged to propagate from the microwave equipment to the quantum processor via the several chambers.

In addition, the quantum processor is sensitive to electromagnetic disturbance and should preferably be shielded. Thermal radiation and magnetic fields are particularly challenging to overcome.

In the coolest chamber in the cryostat, the control signals should be distributed to quantum processor in some packaging arrangement which preferably enables shielding from, i.a., thermal radiation and magnetic fields. Configuring such packaging arrangement becomes more challenging as the number of qubits increases. There is therefore a need for improved packaging arrangements for quantum processors.

### SUMMARY

It is an object of the present disclosure to provide improved packaging arrangements which facilitate distribution of operating signals to a quantum processor. The disclosed packaging arrangements can also be used to facilitate operating the quantum processor under desired conditions in terms of temperature and shielding.

This object is at least in part obtained a packaging arrangement for a quantum processor chip. The quantum processor chip comprises a PCB attachment plate of a conductive material. The PCB attachment plate is arranged to receive a printed circuit board, (PCB) in a stacked configuration where the PCB faces a first surface of the PCB attachment plate. The PCB attachment plate comprises an attachment plate cavity on the first surface, and comprises a ridge arranged at least partly surrounding the attachment plate cavity and arranged protruding from the first surface, wherein the ridge is arranged to receive the quantum processor chip.

The attachment plate cavity in the PCB attachment plate increases the resonance frequency in an effective resonant cavity formed between a quantum processor chip received on the ridge and a bottom of the attachment plate cavity. It is desired to arrange such resonances at frequencies different from any frequency that may affect the quantum processor. In particular, resonances in the frequency span of the control signals should be avoided. This frequency span is normally within 1-10 GHz.

The ridge is arranged to distance a quantum processor chip received on the ridge from the first surface of the PCB attachment plate. The ridge also simplifies assembling the quantum processor to the packaging arrangement. Furthermore, the ridge simplifies alignment of a top surface of the chip with a top surface of a PCB received on the PCB attachment plate. Here, the top surfaces are surfaces facing away from the first surface of the PCB attachment plate. The ridge can also be used to align a PCB, received on the PCB attachment plate, with the PCB attachment plate. The greater number of qubits, the greater number of signals to distribute, which puts more stringent requirements on alignment. For these reasons, the ridge simplifies signal distribution to the quantum processor chip.

According to aspects, the ridge comprises one or more openings for receiving an adhesive for attaching the quantum processor chip to the PCB attachment plate. An opening can be seen as a gap in the ridge. The bottom of a gaps may be flush with the first surface of the PCB attachment plate. An opening can have other shapes as well, such as a cylindrical hole or more general shapes. The one or more openings reduce the risk of excessive adhesive flowing up onto the top surface of a quantum processor chip received on the ridge. Here, the top surface is the surface facing away from the attachment plate cavity. Preferably, the one or more opening are at least partly arranged on an inner side of the ridge, where the inner side of the ridge faces the attachment plate cavity. This way, excessive adhesive can flow into the cavity, which further reduces the risk of excessive adhesive flowing up onto the top surface of the chip. Although excessive adhesive is not preferred in the cavity or anywhere, the top surface of the chip is the most undesired location since it would severely affect the quantum processor.

According to aspects, the first surface of the PCB attachment plate comprises one or more attachment points for receiving an adhesive for attaching the PCB to the PCB attachment plate, wherein the respective attachment points are at least partly surrounded by a trench in the PCB attachment plate. The attachment points may be circular patches where the respective trenches are circular openings surrounding the circular patches. The attachment points and trenches may comprise other shapes as well. The trenches reduce the risk of excessive adhesive flowing up onto a top surface of a PCB arranged on the PCB attachment plate through via holes comprised in the PCB. Here, the top surface is a surface facing away from the first surface of the PCB attachment plate.

According to aspects, the ridge forms a rectangular shape comprising four sections extending along respective four sides of the rectangular shape. In that case, two adjacent sections may have a first width and other two sections have a second width, wherein the widths are in a dimension along the first surface of the PCB attachment plate and along a direction perpendicular to the respective extension directions of the sections, wherein the first width is larger than the second width. This enables rotational and translational alignment with a PCB arranged on the PCB attachment plate.

According to aspects, the packaging arrangement further comprises the PCB, where the PCB is arranged stacked with the PCB attachment plate. The PCB comprises an aperture for receiving the quantum processor chip. The PCB also comprises a plurality of transmission lines where respective first ends of the transmission lines are arranged to be connected to the quantum processor chip and corresponding second ends are arranged to be connected to respective cables. The first and the second ends are arranged on a first surface of the PCB facing away from the of the PCB attachment plate. The PCB aperture is arranged to surround the ridge of the PCB attachment plate. The PCB aperture is a through hole through the PCB. The PCB aperture preferably has shape matched to the shape of the ridge. Normally, both are rectangular.

According to aspects, the aperture of the PCB comprises a rectangular shape and is arranged flush against the two sections of the ridge with the first width. This provides rotational and translational alignment of the PCB with the PCB attachment plate. Such alignment is very important when connecting a quantum processor chip to the PCB since the transmission lines are tightly spaced. The greater number of qubits, the greater number of transmission lines, which in turn reduces the spacing of the transmission lines.

According to aspects, two perpendicular sides of the rectangular PCB aperture are longer by a length x, respectively, compared to corresponding sides of an outer perimeter of the rectangular ridge, and wherein the first width of the ridge is larger than the second width of the ridge by the length x. Using such arrangement enables an equal distance from an edge of the PCB aperture to an edge of a quantum processor chip received centrally on the ridge for all sides of the chip, while simultaneously providing rotational and transitional alignment of the PCB relative to the PCB attachment plate, and while accounting for manufacturing tolerances of the PCB.

According to aspects, the packaging arrangement further comprises a chip cover plate arranged on the first surface of the PCB to cover the PCB, where the chip cover plate comprises a cover plate cavity arranged facing the PCB aperture. This shields a quantum processor chip arranged on the ridge from electromagnetic radiation.

According to aspects, the chip cover plate is attached to the PCB and/or PCB attachment plate by at least one bolt, screw, or the like extending through the cover plate cavity. This effectively makes a resonant cavity formed between PCB cover plate and a quantum processor chip received on the ridge electrically smaller, which increases the resonant frequency. As mentioned, it is desired to arrange such resonances at frequencies different from any frequency that may affect the quantum processor.

According to aspects, the cover plate cavity comprises at least one protrusion protruding from a bottom of the cover plate cavity. This may further increase the resonance frequency in the resonant cavity formed between PCB cover plate and a quantum processor chip received on the ridge.

According to aspects, the packaging arrangement further comprises a receiver arrangement comprising a first receiver plate. The PCB and the PCB attachment plate are arranged stacked with the receiver arrangement with the first surface of the PCB facing the first receiver plate. The first receiver plate comprises a plurality of through holes for receiving respective cables for connecting to respective second ends of the transmission lines of the PCB, where the through holes are arranged facing respective second ends of the transmission lines. The second ends of the transmission lines of the PCB are preferably arranged in a predetermined pattern. Consequently, the through holes facing respective second ends are also arranged in the predetermined pattern. This way it is possible to have a single receiver arrangement when testing a plurality of different quantum processor chips. Different chips can be arranged on different sets of PCBs and PCB attachment plates, which can be received in a standardized receiver arrangement.

According to aspects, the receiver arrangement further comprises a second receiver plate arranged to encapsulate the PCB, the PCB attachment plate, and the optional chip cover plate between the first and the second receiver plates. The two receiver plates can be attached to each other by screws, bolts, or the like. The encapsulation provides shielding from electromagnetic radiation. Preferably, the first receiver plate comprises a stepped edge engaged with a corresponding shape of the second receiver plate. This improves electromagnetic shielding since it blocks line of sight into receiver arrangement.

According to aspects, the packaging arrangement further comprises a first set of cables being coaxial cables, where respective first ends of the coaxial cables are connected to the respective second ends of the transmission lines of the PCB, and where the coaxial cables are spring loaded between the first receiver plate and the PCB. This arrangement provides a packaging arrangement where it is quick and easy to assemble the PCB into the receiver arrangement.

According to aspects, the packaging arrangement further comprises a first cable plate comprising a plurality of cable connectors connected to respective second ends of the coaxial cables in the first set of cables. The cable connectors are also arranged to connect to a second set of cables directed away from the packaging arrangement. The first cable plate with cable connectors provide shielding from electromagnetic radiation.

According to aspects, the packaging arrangement further comprises the second set of cables connected to the cable connectors and a second cable plate comprising a plurality of through holes through which respective cables in the second set are arranged extending through. The second cable plate provides mechanical stability to the second set of cables.

There is also disclosed herein a set comprising the packaging arrangement and the quantum processor chip according to the discussions above.

There is also disclosed a method for assembling a quantum processor chip to packaging arrangement according to the discussions above. The method comprises: applying a first adhesive to PCB attachment plate and arranging the PCB on the PCB attachment plate; pressing the PCB to the PCB attachment plate, wherein the PCB aperture is aligned with the ridge, and curing the first adhesive; applying a second adhesive to the ridge and arranging the quantum processor chip on the ridge; pressing the quantum processor chip to the ridge and curing the second adhesive; and arranging wire bonds between respective first ends of the transmission lines of the PCB.

The methods disclosed herein are associated with the same advantages as discussed above in connection to the different apparatuses.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated. Further features of, and advantages with, the present invention will become apparent when studying the appended claims and the following description. The skilled person realizes that different features of the present invention may be combined to create embodiments other than those described in the following, without departing from the scope of the present invention.

### BRIEF DESCRIPTION OF THE DRAWINGS

The present disclosure will now be described in more detail with reference to the appended drawings, where:

FIG. 1 shows a packaging arrangement in a cryostat;

FIGS. 2-5 show packaging arrangements;

FIG. 6 shows parts of a PCB attachment plate;

FIG. 7 is a schematic illustration a PCB aperture, ridge, and quantum processor chip;

FIG. 8 shows a chip cover plate;

FIGS. 9-10 show different views of a section of a printed circuit board; and

FIG. 11 is a flow chart illustrating methods.

### DETAILED DESCRIPTION

Aspects of the present disclosure will now be described more fully with reference to the accompanying drawings. The different devices and methods disclosed herein can, however, be realized in many different forms and should not be construed as being limited to the aspects set forth herein. Like numbers in the drawings refer to like elements throughout.

The terminology used herein is for describing aspects of the disclosure only and is not intended to limit the invention. As used herein, the singular forms “a”, “an” and “the” are intended to include the plural forms as well, unless the context clearly indicates otherwise.

As mentioned, there is a need for improved packaging arrangements which facilitate distribution of operating signals to a quantum processor and that preferably also facilitate operating the quantum processor under desired conditions in terms of temperature and shielding.

To setup a quantum processor is time-consuming process comprising connecting the quantum processor to the microwave instrumentations at room temperature via the cryostat. There is a risk of mistakes during this setup since the cabling is complex. Unfortunately, it is required to cool down the system to verify that the setup is correct, which also is time-consuming. Furthermore, shielding the quantum processor from, i.a., thermal radiation and magnetic fields must also be done properly during the setup.

As the number of qubits increases, spacing becomes more of a problem. It is particularly challenging to fit the signal distribution between the chip to some cabling arrangement in the coolest chamber in the cryostat. The setup time also increases with the number of qubits. Correspondingly, the error rate also increases. In addition, thermal radiation may increase due to larger losses from the larger number of cables and connectors.

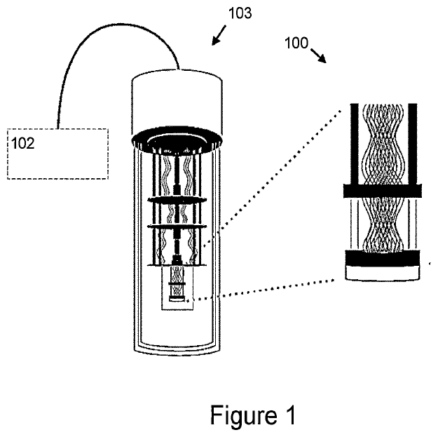

Therefore, there is disclosed herein a packaging arrangement 100 for a quantum processor chip 101. The quantum processor chip is an integrated circuit constituting the quantum processor. FIG. 1 shows an example cryostat 103 in which the disclosed packaging arrangement 100 is arranged. In this example, control circuitry 102, i.e., microwave equipment/instrumentation is arranged in room temperature and is connected to quantum processor chip 101 comprised in the packaging arrangement. The figure further shows several cryostat chambers and cabling from the control circuitry to a quantum processor chip arranged in the packaging arrangement 100.

More specifically, the disclosed packaging arrangement 100 comprises a PCB attachment plate 120, where the PCB attachment plate 120 comprises a conductive material such as copper. Furthermore, the PCB attachment plate is arranged to receive a printed circuit board (PCB) 120 in a stacked configuration where the PCB faces a first surface of the PCB attachment plate. The PCB attachment plate 120 comprises an attachment plate cavity 121 on the first surface. The PCB attachment plate also comprises a ridge 122 arranged at least partly surrounding the attachment plate cavity and arranged protruding from the first surface. The ridge is arranged to receive the quantum processor chip 101.

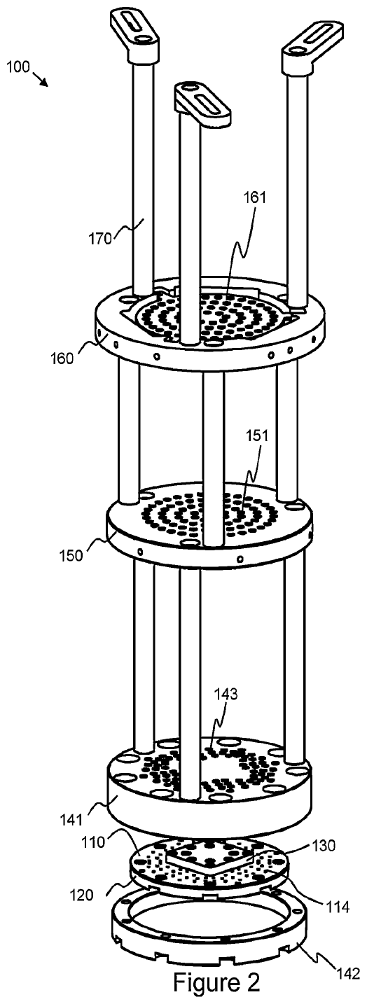

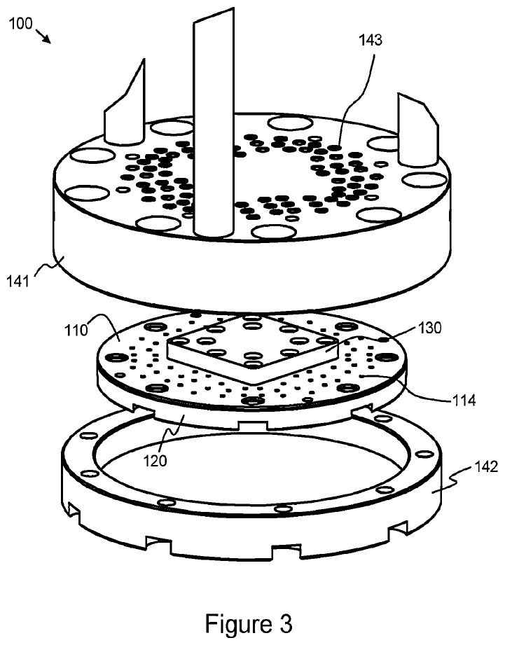

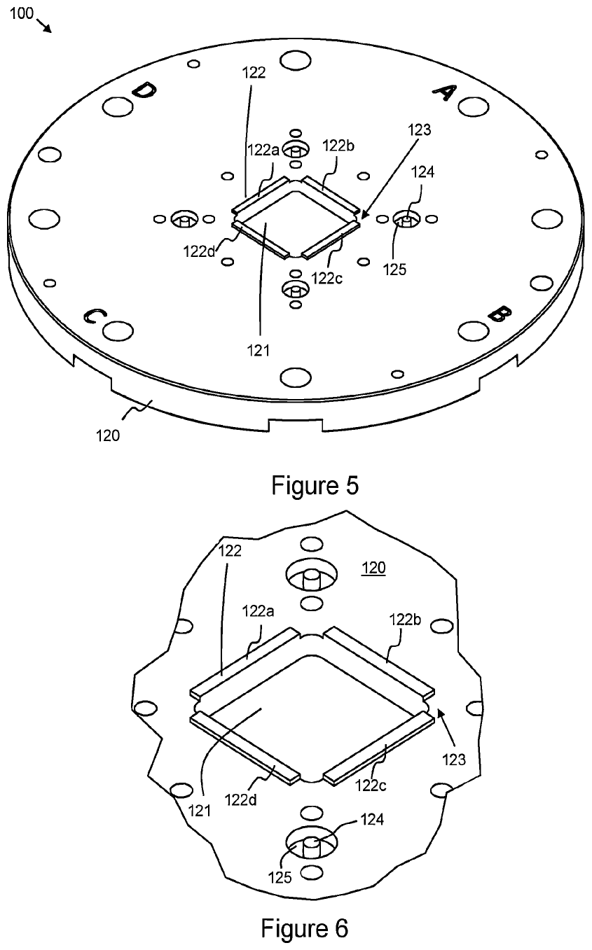

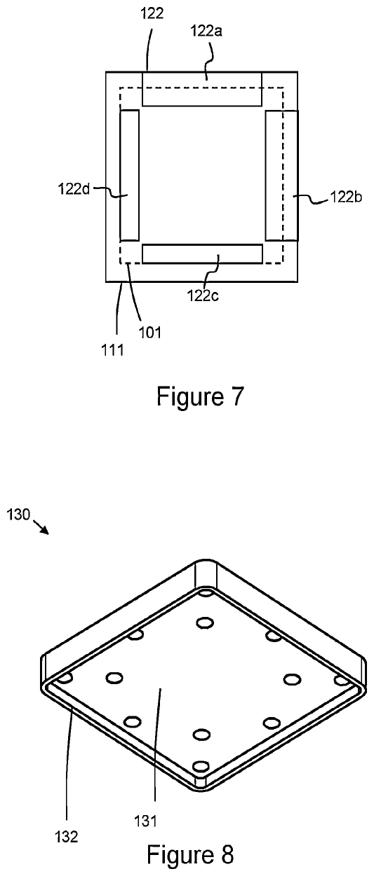

FIGS. 2-6 show different aspects of an example packaging arrangement 100. FIG. 5, in particular, shows a detailed view of the PCB attachment plate 120. FIG. 6 shows a zoomed in section of the PCB attachment plate of FIG. 5. Furthermore, FIG. 7 shows a schematic illustration a PCB aperture, ridge, and quantum processor chip.

A stacked configuration comprises a plurality of layers. The PCB attachment plate 120 is a layer and the PCB, which the PCB attachment plate is arranged to receive, is also a layer. A layer has two sides, or faces, and is associated with a thickness.

The thickness is much smaller than the dimension of the faces. According to some aspects, a layer is rectangular or square. However, more general shapes are also applicable, including circular or elliptical disc shapes. The stacked configuration is stacked in the sense that layers are arranged on top of each other. In other words, the layered structure can be seen as a sandwich structure. Each layer is preferably flat, but can also be arcuate.

Referring mainly to FIGS. 5 and 6, the attachment plate cavity 121 is arranged to suppress cavity modes. The quantum processor chip 101, arranged to be received on the ridge 122, normally has a dielectric substrate bottom facing the ridge and attachment plate cavity 121. This bottom of the substrate typically lacks a ground plane. Therefore, if the quantum processor chip would be arranged on a planar metal surface, an effective resonant cavity would be formed between this metal surface and conducive layers in the chip. Since the substrate at the bottom of quantum processor chips typically has a large dielectric constant, e.g., above 10, this effective resonant cavity is electrically large compared to, e.g., resonant cavities comprising air. The electrical length is the length in terms of a phase shift introduced by the distance for some frequency. Therefore, the effective resonant cavity may be resonant at frequencies which are desired for controlling the quantum processor, typically within 1-10 GHz, which is highly undesired.

The attachment plate cavity 121 forms an enlarged resonant cavity when the quantum processor chip 101 is received on the ridge 122. This resonant cavity is much smaller electrically compared to example in the previous paragraph since it also comprises air, or vacuum or some other gas. This way, the resonant frequencies can be pushed up to higher frequencies, preferably above 10 GHz or so. More generally, it is desired to arrange resonances at frequencies different from any frequency that may affect the quantum processor. The dimensions of the cavity can be selected to arrange resonance at some desired frequency/frequencies.

Although the example packaging arrangement 100 comprises a single attachment plate cavity 121 with corresponding ridge 122, the disclosed packaging arrangement may in general comprise any number of attachment plate cavities with corresponding ridges for receiving respective quantum processor chips. For example, there may be four separate attachment plate cavities with corresponding ridges arranged on a similar amount of space as the single attachment plate cavity in FIGS. 5-6. In this case the four cavities are individually smaller than the single one.

The attachment plate cavity 121 is an opening in the PCB attachment plate, which can be obtained, e.g., from milling the first surface of the PCB attachment plate. The cavity comprises a rectangular shape with rounded corners in the examples of FIGS. 5-6, but may have other shapes such as circular, triangular, or other general shapes. The attachment plate cavity 121 may have a depth relative to the first surface of the PCB attachment plate 120 of, e.g., 0.5-5 mm. The depth should normally not be larger than when it is great enough to support an electromagnetic mode in that direction in the frequency band of interest, e.g., 1-10 GHZ. Furthermore, the depth may be selected smaller since it is often desired to reduce space in that dimension.

As mentioned, the ridge is arranged to receive the quantum processor chip 101. In other words, the quantum processor chip can be mounted onto the ridge, using, e.g., an adhesive. The quantum processor can be seen as a lid covering the attachment plate cavity when attached onto the ridge.

The ridge 122 is arranged to distance a quantum processor chip 101 received on the ridge from the first surface of the PCB attachment plate 120. Preferably, when the quantum processor chip received on the ridge and when PCB 110 is arranged on the PCB attachment plate 120, a surface of the quantum processor chip facing away from the of the PCB attachment plate is arranged flush with a first surface of the PCB facing away from the of the PCB attachment plate. In other words, these two surfaces are level with respect to a normal direction from the first surface of the PCB attachment plate. Normally, the two surfaces can be arranged flush within a tolerance of plus/minus 10 micrometers.

The ridge 122 is preferably arranged to partly surround the attachment plate cavity to provide a support for the quantum processor chip. The ridge 122 may, e.g., be a continuous and uniform protruding section surrounding the cavity. The cross section of the ridge is normally rectangular, although other shapes are also possible. The ridge may be obtained by milling the first surface of the PCB attachment plate 120. Preferably, the inner side of the ridge is arranged flush with attachment plate cavity 121. If the cross section of the ridge is rectangular, the inner side is on a surface facing inwards to the attachment plate cavity. This way, a large portion of the bottom of the quantum processor chip faces the attachment plate cavity.

The ridge may have a width corresponding to 1/20 to ⅛ of a length of the cavity measured along the first surface of the PCB attachment plate 120. The width of the ridge at a certain point is measured in a dimension along the first surface of the PCB attachment plate 120 and along a direction perpendicular to an extension direction of the ridge at that point.

The ridge 122 may comprise one or more openings 123 for receiving an adhesive for attaching the quantum processor chip 101 to the PCB attachment plate 120. In FIGS. 5-6, the attachment plate cavity 121 is square and the corresponding ride 122 is also square. Furthermore, four openings 123 are arranged at each corner of the ridge. Here, the openings be seen as a respective gaps in the ridge. The bottom of these gaps may be flush with the first surface of the PCB attachment plate. An opening can have other shapes as well, such as a cylindrical hole or more general shapes. The openings can, e.g., be obtained by milling the ridge. The one or more openings reduce the risk of excessive adhesive flowing up onto the top surface of the quantum processor chip, i.e., the surface facing away from the attachment plate cavity, when a quantum processor chip 101 is received on the ridge. Preferably, the one or more opening are at least partly arranged on the inner side of the ridge. This way, excessive adhesive can flow into the cavity, which further reduces the risk of excessive adhesive flowing up onto the top surface of the chip. Although excessive adhesive is not preferred in the cavity or anywhere, the top surface of the chip is the most undesired location since it would severely affect the quantum processor.

The adhesive for attaching the quantum processor chip 101 to the ridge 122 can be, e.g., a glue suitable for vacuum.

The first surface of the PCB attachment plate 120 may comprise one or more attachment points 124 for receiving an adhesive for attaching the PCB 101 to the PCB attachment plate 120, where the respective attachment points are at least partly surrounded by a trench 125 in the PCB attachment plate 120. In FIGS. 5-6, the attachment points are circular patches and respective trenches are circular openings/grooves surrounding the circular patches. The circular patches thus form cylindrical protrusions from the bottom of the trenches. The attachment points may comprise other shapes as well. The trenches are preferably formed by milling the first surface of the PCB attachment plate 120. The trenches reduce the risk of excessive adhesive flowing up onto a top surface of a PCB arranged on the PCB attachment plate through via holes comprised in the PCB. Here, the top surface is a surface facing away from the first surface of the PCB attachment plate.

The adhesive for attaching a PCB 110 to the PCB attachment plate 120 can be, e.g., a glue suitable for vacuum. The PCB may also be attached to the PCB attachment plate using bolts, screws, or the like.

The ridge 122 may form a rectangular shape comprising four sections 122a, 122b, 122c, 122d extending along respective four sides of the rectangular shape. Furthermore, two adjacent sections 122a, 122b have a first width and other two sections 122c, 122d have a second width. The widths are measured in a dimension along the first surface of the PCB attachment plate 120 and along a direction perpendicular to the respective extension directions of the sections, wherein the first width is larger than the second width. This enables rotational and translational alignment with a PCB 110 arranged on the PCB attachment plate 120. The widths are preferably constant along the respective sections.

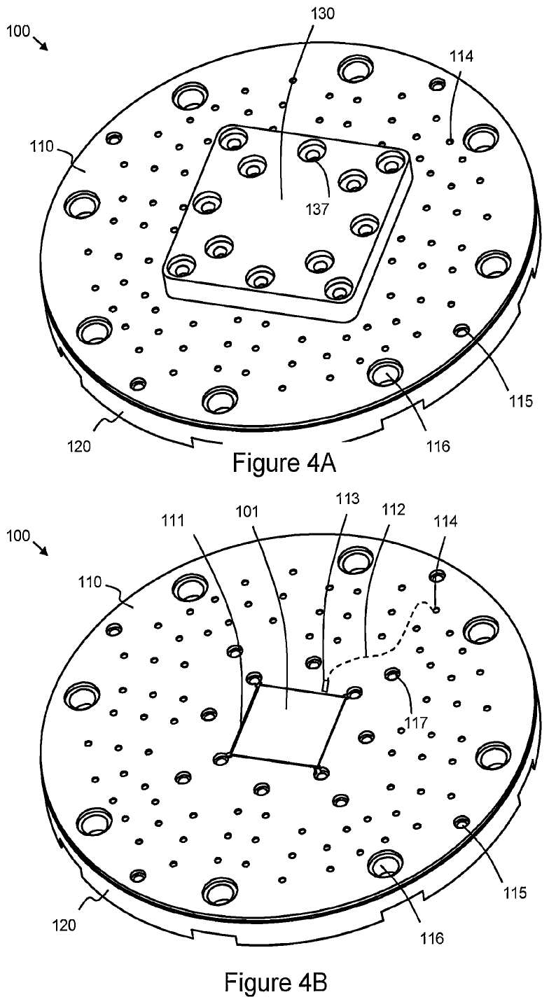

With reference to FIGS. 4B and 9-10, the packaging arrangement 100 may further comprise the PCB 110, where the PCB is arranged stacked with the PCB attachment plate 120. The PCB 110 comprises an aperture 111 for receiving the quantum processor chip 101. The PCB further comprises a plurality of transmission lines 112 where respective first ends 113 of the transmission lines are arranged to be connected to the quantum processor chip and corresponding second ends 114 are arranged to be connected to respective cables. The first and the second ends are arranged on a first surface of the PCB facing away from the of the PCB attachment plate 120. The PCB aperture 111 is arranged to surround the ridge 122 of the PCB attachment plate 120.

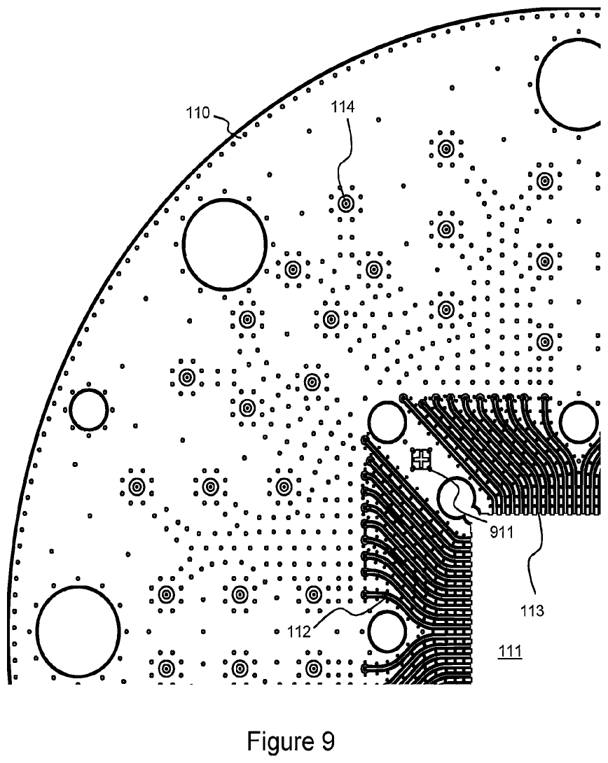

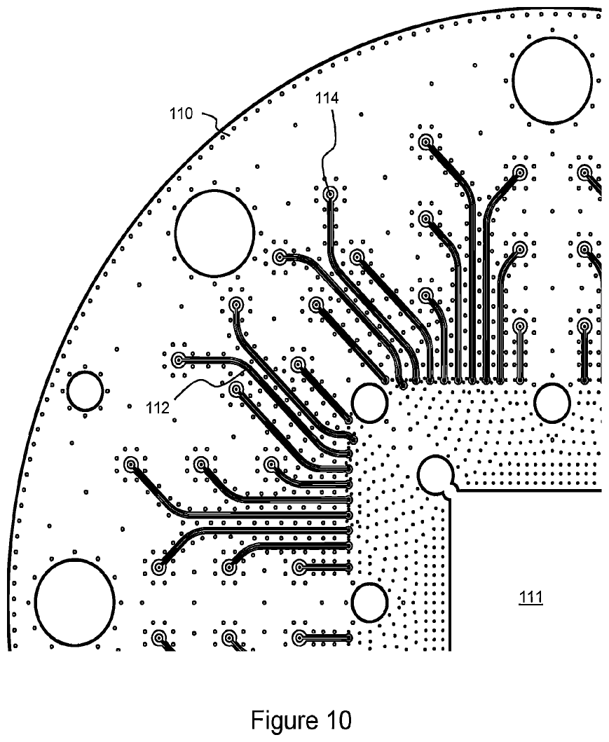

FIG. 4B shows the PCB stacked with the PCB attachment plate 120. In this example, the first surface of the PCB has been simplified by not fully showing the conductive layer on the first surface, which comprises, i.a., the transmission lines and the first ends. In FIG. 4B, the numbers 112 and 113 show example locations of a first end and of a transmission line, respectively. FIG. 9 shows a detailed view of an example first surface of the PCB. FIG. 10 shows a detailed view of the conductive layer below the top layer in FIG. 9. FIGS. 9-10 show roughly a quarter of a circular PCB. The remaining parts of the PCB look similar due to symmetry.

The PCB aperture 111 is a through hole through the PCB 110. The PCB aperture preferably has shape matched to the shape of the ridge. Normally, both are rectangular. Typically, the size of the PCB aperture 111 is designed to have a margin relative to the size of the ridge 122 to account for manufacturing tolerances. For example, the PCB aperture may be larger in one direction by 100 micrometers compared to the outer dimensions of the ridge in the same direction.

At least part of a transmission line is preferably stripline. In FIGS. 9-10, the transmission lines are stripline in connection to the second ends 114. The available space for the transmission lines is reduced as the transmission line approaches the PCB aperture 111. Therefore, the striplines in the example transition into respective microstrip lines in connection to the aperture. In FIGS. 9-10, the second ends comprise respective center vias connected to the respective center lines in the striplines. The center vias are surrounded by grounded vias. The first ends are respective ends of the microstrip lines. The respective transitions from the center lines of the striplines to the microstrips also comprises respective vias. In general, however, the transmission lines and first and second ends may be other different types. The striplines typically require three conducive layers in the PCB. In general, however, the PCB may comprise any number of layers.

The PCB may have reference markings 911 for coordination during assembly, e.g., used by an automatic bonding machine arranged to bond the first ends 113 of the transmission line to the quantum processor chip 101.

If the packaging arrangement 100 is arranged to receive a plurality of quantum processor chips and comprises a plurality of attachment plate cavities with corresponding ridges, the PCB may comprise corresponding PCB apertures arranged to surround the respective ridges of each attachment plate cavity.

According to aspects, the aperture 111 of the PCB 110 comprises a rectangular shape and is arranged flush against the two sections 122a, 122b with the first width. This provides rotational and translational alignment of the PCB with the PCB attachment plate 120. Rotational and translational alignment are very important when connecting the quantum processor chip to the PCB since the transmission lines are tightly spaced. The greater number of qubits, the greater number of transmission lines, which in turn reduces the spacing of the transmission lines.

FIG. 7 is a schematic illustration a PCB aperture 111, ridge 122, and quantum processor chip 101 arranged on the ridge. The larger first widths of the ridge are used to compensate for margins in the PCB aperture size, where the margin is used to account for manufacturing tolerances in the PCB aperture size. The quantum processor chip can typically be aligned on the ridge by using optical aids. The quantum processor is preferably arranged centered in the PCB aperture 111.

According to aspects, two perpendicular sides of the rectangular PCB aperture 111 are longer by a length x, respectively, compared to corresponding sides of an outer perimeter of the rectangular ridge 122, and wherein the first width of the ridge is larger than the second width of the ridge by the length x. Using such arrangement enables an equal distance from an edge of the PCB aperture to an edge of a quantum processor chip received centrally on the ridge for all sides of the chip, while simultaneously providing rotational and transitional alignment of the PCB relative to the PCB attachment plate, and while allowing for manufacturing tolerances of the PCB.

In an example, the manufacturing tolerances of the length of a side of a square PCB aperture 111 is 0.1 mm, the ridge is square shaped and has a side of 1 mm, and the aperture is square and has a side of 1.1 mm. In this case, the second width can be 0.1 mm and the first width can be 0.2 mm. In this example, the quantum chip is square with a side of 0.9 mm. The chip is arranged centrally in on the ridge and is connected to the PCB via bond wires which cover a distance of at least 0.1 mm.

Equal length bond wires are preferred to connect the first ends 113 of the transmission lines 112 to the quantum processor chip around the aperture. Equal length bond wires simplify manufacturing and provides equal matching for all connections.

The packaging arrangement 100 may further comprise a chip cover plate 130 arranged on the first surface of the PCB 110 to cover the PCB aperture 111. The chip cover plate comprises a cover plate cavity 131 arranged facing the PCB aperture. The chip cover plate preferably comprises a conductive material such as copper.

FIGS. 2-4A show examples when the cover plate 130 is arranged on the first surface of the PCB 110. FIG. 8 shows a surface of the cover plate facing the PCB aperture 111. In FIG. 8, the cover plate cavity 131 is visible.

The cover plate cavity 131 is an opening in the cover plate, which can be obtained, e.g., from milling the surface of the cover plate facing the PCB aperture. The cavity comprises a rectangular shape with rounded corners in the example of FIG. 8, but may have other shapes such as circular, triangular, or other general shapes. The remainder 132 of the surface of the cover plate facing the PCB aperture can be seen as a protruding ridge relative to the bottom of the cover plate cavity 131. The cross section of the cover plate cavity 131 is normally larger than the cross section of the PCB aperture 111, and cross section of the cover plate 130 is normally larger than the cross section of the cover plate cavity 131. Here, a cross section is measured along directions parallel to the surface of the PCB 110.

The cover plate cavity 131 may have a depth relative to the remainder of the surface of the cover plate facing the PCB aperture of 0.01-3 mm to accommodate any vertical structures (i.e., structures protruding in a normal direction from the PCB and/or chip) such as bond wires.

The cover plate 130 comprises a conductive material such as copper and is arranged to shield the quantum processor chip from electromagnetic radiation. Preferably, the remainder 132 is arranged to contact a conductive layer on the PCB. The cover plate cavity 131 is arranged so that the quantum processor chip 101 and connection from the chip to the transmission lines are not electrically shorted by the cover plate. When the transmission lines are arranged on the top surface in connection to the quantum processor chip, as, e.g., the microstrip in FIG. 9, the cover plate cavity 131 is also arranged so that those parts of the transmission lines are not electrically shorted by the cover plate.

If the packaging arrangement 100 is arranged to receive a plurality of quantum processor chips and comprises a plurality of attachment plate cavities with corresponding ridges, the chip cover plate may comprise corresponding cover plate cavities arranged to face the respective attachment plate cavities. Alternatively, the chip cover plate may comprise a single cover plate cavity arranged to face all attachment plate cavities.

Referring to FIGS. 4A-4B, the chip cover plate 130 may be attached to the PCB 110 and/or PCB attachment plate 120 by at least one bolt, screw, or the like extending through the cover plate cavity 131. When the chip cover plate is arranged covering a quantum processor chip, a resonant cavity is formed between the cover plate cavity and the chip. It is desired that the bolt, screw, or the like extends through the cover plate cavity 131 since that effectively makes the resonant cavity electrically smaller, which increases the resonant frequency. As mentioned, it is desired to push such resonances to above the frequencies of the control signals, normally above 10 GHz or so.

In the example of FIGS. 4A-4B, it can be seen that four bolts can be arranged in connection to each corner of the PCB aperture 111. This is normally the closest such bolts can be arranged to the quantum processor chip since the sides the chip are typically fully occupied by bond wires between the chip and the transmission lines of the PCB.

The packaging arrangement 100 is typically at least partly assembled in room temperature before it is inserted into the cryostat. Thus, the packaging arrangement may experience a temperature difference of about 300 degrees Celsius. The various parts of the packaging arrangement 100 may present different thermal expansions relative to each other. It is desired that the position of a quantum processor chip 101 arranged in the packaging arrangement 100 moves as little as possible relative to the first ends 113 of the transmission lines. Such movement may affect the connection between the first ends 113 and the quantum processor chip. For example, bond wires constituting such connections may break or detach from the PCB and/or quantum processor chip. Therefore, the PCB 110 and the PCB attachment plate 120 and preferably also the chip cover plate 130, are mainly connected to each other via bolts, screws, or the like arranged in proximity to the quantum processor chip. This way, any relative movement of the parts of the packaging transition due to thermal expansion moves relative to the position of the quantum processor chip.

According to aspects, the PCB 110, the PCB attachment plate 120, and the chip cover plate 130 are connected to each other by a first number of bolts, screws, or the like. A second number of number of bolts, screws, or the like are arranged to connect the PCB 110 to the PCB attachment plate 120. The first number is larger than second number, preferably by at least a factor of two. Alternatively, no bolts, screws, or the like are arranged to connect the PCB 110 to the PCB attachment plate 120.

In FIGS. 4A-4B, the PCB 110, the PCB attachment plate 120, and the chip cover plate 130 comprise twelve holes, respectively, for attaching these three parts together. These holes are shown as 137 in the cover plate in FIG. 4A and as 117 in the PCB in FIG. 4B. Furthermore, the PCB 110 and the PCB attachment plate 120 comprise four holes, respectively, for attaching these two parts together. These holes are shown as 115 in FIG. 4A-4B. The PCB 110 and the PCB attachment plate 120 also comprise eight through holes, respectively, for attaching the set of PCB and PCB attachment plate to a first receiver plate 141, which is discuss below. These holes are shown as 116 in FIGS. 4A-4B.

The cover plate cavity 131 may comprise at least one protrusion protruding from a bottom of the cover plate cavity. The protrusion may, e.g., be a cylindrical structure extending towards the PCB aperture 111. When a quantum processor chip 101 is received in the packaging arrangement 100, the protrusion may or may not be in contact with the chip. The protrusion is arranged to disrupt the electrical fields in the resonant cavity formed between the cover plate cavity 131 and the quantum processor chip, and thereby increase the resonance frequency.

The packaging arrangement 100 may further comprise a receiver arrangement 140 comprising a first receiver plate 141, where the PCB 110 and the PCB attachment plate 120 are arranged stacked with the receiver arrangement with the first surface of the PCB facing the first receiver plate 141. The first receiver plate comprises a plurality of through holes 143 for receiving respective cables for connecting to respective second ends 114 of the transmission lines 112 of the PCB 110. The through holes 143 are arranged facing respective second ends 114 of the transmission lines 112. In other words, a line extending in a normal direction of the first surface of the PCB from a second end 114 intersects with a through hole 143. The first receiver plate preferably comprises a conductive material such as copper.

The placement of the second ends 114 of the transmission lines 112 of the PCB 110 are preferably arranged in a predetermined pattern. Consequently, the through holes facing respective second ends are also arranged in the predetermined pattern. This way it is possible to have a single receiving arrangement when testing a plurality of different quantum processor chips 101. Different chips can be arranged on different sets of PCBs and PCB attachment plates 120, which can be received in a standardized receiver arrangement 140.

The receiver arrangement 140 may further comprise a second receiver plate 142 arranged to encapsulate the PCB 110, the PCB attachment plate 120, and the optional chip cover plate 130 between the first 141 and the second 142 receiver plates. The two receiver plates can be attached to each other by screws, bolts, or the like. The encapsulation provides shielding from electromagnetic radiation. The second receiver plate preferably comprises a conductive material such as copper.

The first receiver plate 141 may comprise a stepped edge engaged with a corresponding shape of the second receiver plate 142. The stepped edge of the first receiver plate may comprise a plurality of steps. The corresponding shape of the second receiver plate may be one or more corresponding steps. This improves electromagnetic shielding since it blocks line of sight into receiver arrangement. For example, the first receiver plate may comprise a ridge around the rim of the plate, where this ridge has a step arranged on the inner part of the ridge. The second receiver plate can be received on that step.

The packaging arrangement 100 may further comprise a first set of cables being coaxial cables, where respective first ends of the coaxial cables are connected to the respective second ends 114 of the transmission lines 112 of the PCB 110, and where the coaxial cables are spring loaded between the first receiver plate 141 and the PCB. The spring loaded cables may be coaxial cables and comprise respective springs arranged to push the cables onto the PCB relative to the first receiver plate 141. This arrangement provides a packaging arrangement 100 where it is quick and easy to assemble a set of PCB, PCB attachment plate, and chip cover plate into the receiver arrangement. Since there can be a vast number of cables, e.g., 80, a quick connection is desired. In contrast, individually screwing 80 cables on to the PCB would be highly undesired.

The packaging arrangement 100 may further comprise a first cable plate 150 comprising a plurality of cable connectors connected to respective second ends of the coaxial cables in the first set of cables, wherein the cable connectors are also arranged to connect to a second set of cables directed away from the packaging arrangement 100. FIG. 2 shows an example first cable plate 150 with through holes 151. The cable connectors are not shown in the figure but are arranged in the through holes. The first cable plate with cable connectors provides shielding from electromagnetic radiation. The first cable plate preferably comprises a conductive material such as copper.

The packaging arrangement 100 may further comprise the second set of cables connected to the cable connectors and a second cable plate 160 comprising a plurality of through holes 161 through which respective cables in the second set are arranged extending through. The second cable plate provides mechanical stability to the second set of cables. In the example of FIG. 2, the second cable plate 160 comprises two parts: one part connected to rods 170 and a second part comprising the through holes 161, where the second part is arranged centrally in the first part. The second cable plate preferably comprises a conductive material such as copper.

FIG. 2 further shows rods 170 arranged to support the receiver arrangement 140, the first cable plate 150, and the second cable plate 160. The packaging arrangement 100 may further comprise a magnetic shielding arrangement arranged to at least partly surround the PCB 110, the PCB attachment plate 120, the chip cover plate 130, the receiver arrangement 140, the first cable plate 150, the second cable plate 160, the first set of cables, and/or the second set of cables. Such magnetic shielding arrangement may comprise one or more hollow tubes.

There is also disclosed herein a set comprising the packaging arrangement 100 and the quantum processor chip 101 according to the discussions above.

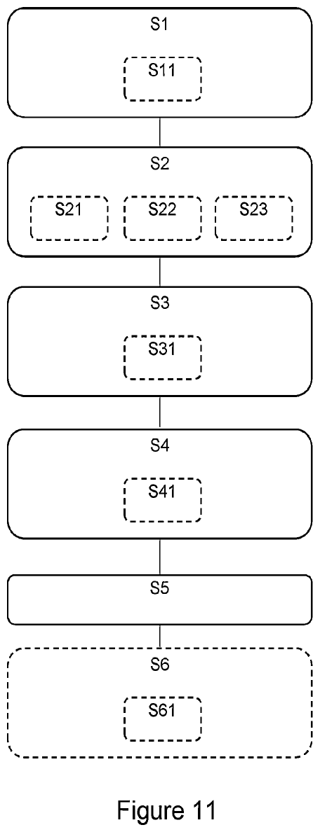

As is exemplified in FIG. 11, there is also disclosed herein a method for assembling a quantum processor chip 101 to a packaging arrangement 100 according to the discussions above. The method comprises applying S1 a first adhesive to PCB attachment plate and arranging the PCB 110 on the PCB attachment plate. Preferably, the PCB attachment comprises the attachment points discussed above, and the adhesive is attached S11 on at least one of these attachment points.

The method further comprises pressing S2 the PCB 110 to the PCB attachment plate 120, wherein the PCB aperture 111 is aligned with the ridge 122, and curing the first adhesive. Preferably, the ridge comprises the sections 122a, 122b, 122c, 122d with the first and second widths according to the discussions above, and the PCB 110 is arranged S21 arranged flush against the two sections 122a, 122b with the first width.

In addition, the PCB 110 may be attached S22 to the PCB attachment plate 120 before the curing of the first adhesive by screws, bolts, or the like between the PCB and the PCB attachment plate in proximity to an outer edge of the PCB, e.g., so the screw/bolt head is flush with the edge. The holes 115 in FIGS. 4A-4B show example locations.

Furthermore, the PCB 110 may be pressed against the PCB attachment plate 120 before the curing of the first adhesive using S23 a first fixture which is of similar size as the chip cover plate 130. The first fixture is removed after curing. The first fixture may be attached to the PCB and/or the PCB attachment plate using screws or bolts, which correspond to the attachment means between the chip cover plate 130 and the PCB and/or the PCB attachment plate. The chip cover plate may be used as the first fixture. Alternatively, the first fixture may correspond to a chip cover plate without a cover plate cavity 131.

The method further comprises applying S3 a second adhesive to the ridge 122 and arranging the quantum processor chip 101 on the ridge. Preferably, the ridge 122 comprises one or more openings 123 according to the discussions above, and the second adhesive is applied S31 in at least one of these one or more openings.

The method further comprises pressing S4 the quantum processor chip 101 to the ridge 122 and curing the second adhesive. Preferably, the chip is pressed S41 using a fixture arranged to distribute an even pressure on the chip.

The method further comprises arranging S5 wire bonds between respective first ends 113 of the transmission lines 112 of the PCB 110 and respective pads arranged on the quantum processor chip 101.

The method may also comprise attaching S6 attaching the chip cover plate 130 to the PCB 110 and PCB attachment plate 120 with screws, bolts, or the like. In that case, any screws, bolts, or the like between the PCB and the PCB attachment plate in 10 proximity to an outer edge of the PCB can optionally be removed S7.

1. A packaging arrangement (100) for a quantum processor chip (101), arranged to be cooled by being placed in a cryostat, the packaging arrangement (100) comprising a PCB attachment plate (120) of a conductive material, wherein the PCB attachment plate is arranged to receive a printed circuit board, PCB, (110) in a stacked configuration where the PCB faces a first surface of the PCB attachment plate, the PCB attachment plate (120) comprising an attachment plate cavity (121) on the first surface, and comprising a ridge (122) arranged at least partly surrounding the attachment plate cavity and arranged protruding from the first surface, wherein the ridge is arranged to receive the quantum processor chip (101).

2. The packaging arrangement (100) according to claim 1, wherein the ridge (122) comprises one or more openings (123) for receiving an adhesive for attaching the quantum processor chip (101) to the PCB attachment plate (120).

3. The packaging arrangement (100) according to claim 1, wherein the first surface of the PCB attachment plate (120) comprises one or more attachment points (124) for receiving an adhesive for attaching the PCB (110) to the PCB attachment plate (120), wherein the respective attachment points are at least partly surrounded by a trench (125) in the PCB attachment plate (120).

4. The packaging arrangement (100) according to claim 1, wherein the ridge (122) forms a rectangular shape comprising four sections (122a, 122b, 122c, 122d) extending along respective four sides of the rectangular shape.

5. The packaging arrangement (100) according to claim 4, wherein two adjacent sections (122a, 122b) have a first width and other two sections (122c,122d) have a second width, wherein the widths are in a dimension along the first surface of the PCB attachment plate (120) and along a direction perpendicular to the respective extension directions of the sections, wherein the first width is larger than the second width.

6. The packaging arrangement (100) according to claim 1, further comprising the PCB (110), where the PCB is arranged stacked with the PCB attachment plate (120), the PCB (110) comprising an aperture (111) for receiving the quantum processor chip (101), and comprising a plurality of transmission lines (112) where respective first ends (113) of the transmission lines are arranged to be connected to the quantum processor chip and corresponding second ends (114) are arranged to be connected to respective cables, where the first and the second ends are arranged on a first surface of the PCB facing away from the of the PCB attachment plate (120), and wherein the PCB aperture (111) is arranged to surround the ridge (122) of the PCB attachment plate (120).

7. The packaging arrangement (100) according to claim 6, wherein the aperture (111) of the PCB (110) comprises a rectangular shape and is arranged flush against the two sections (122a, 122b) with the first width.

8. The packaging arrangement (100) according to claim 7, wherein two perpendicular sides of the rectangular PCB aperture (111) are longer by a length x, respectively, compared to corresponding sides of an outer perimeter of the rectangular ridge (122), and wherein the first width of the ridge is larger than the second width of the ridge by the length x.

9. The packaging arrangement (100) according to claim 6, further comprising a chip cover plate (130) arranged on the first surface of the PCB (110) to cover the PCB aperture (111), wherein the chip cover plate comprises a cover plate cavity (131) arranged facing the PCB aperture.

10. The packaging arrangement (100) according to claim 9, wherein the chip cover plate (130) is attached to the PCB (110) and/or PCB attachment plate (120) by at least one bolt, screw, or the like extending through the cover plate cavity (131).

11. The packaging arrangement (100) according to claim 9, wherein the cover plate cavity (131) comprises at least one protrusion protruding from a bottom of the cover plate cavity.

12. The packaging arrangement (100) according to claim 1, further comprising a receiver arrangement (140) comprising a first receiver plate (141), where the PCB (110) and the PCB attachment plate (120) are arranged stacked with the receiver arrangement with the first surface of the PCB facing the first receiver plate (141), the first receiver plate comprising a plurality of through holes (143) for receiving respective cables for connecting to respective second ends (114) of the transmission lines (112) of the PCB (110), wherein the through holes (143) are arranged facing respective second ends (114) of the transmission lines (112).

13. The packaging arrangement (100) according to claim 12, wherein the receiver arrangement (140) further comprises a second receiver plate (142) arranged to encapsulate the PCB (110), the PCB attachment plate (120), and the optional chip cover plate (130) between the first (141) and the second (142) receiver plates.

14. The packaging arrangement (100) according to claim 13, wherein the first receiver plate (141) comprises a stepped edge engaged with a corresponding shape of the second receiver plate (142).

15. The packaging arrangement (100) according to claim 12, further comprising a first set of cables being coaxial cables, wherein respective first ends of the coaxial cables are connected to the respective second ends (114) of the transmission lines (112) of the PCB (110), and where the coaxial cables are spring loaded between the first receiver plate (141) and the PCB.

16. The packaging arrangement (100) according to claim 15, further comprising a first cable plate (150) comprising a plurality of cable connectors connected to respective second ends of the coaxial cables in the first set of cables, wherein the cable connectors are also arranged to connect to a second set of cables directed away from the packaging arrangement (100).

17. The packaging arrangement (100) according to claim 16, further comprising the second set of cables connected to the cable connectors and a second cable plate (160) comprising a plurality of through holes (161) through which respective cables in the second set are arranged extending through.

18. A set comprising the packaging arrangement (100) according to claim 1 and the quantum processor chip (101).

19. A method for assembling a quantum processor chip (101) to a packaging arrangement (100) according to claim 1, wherein the method comprises:
applying (S1) a first adhesive to PCB attachment plate and arranging the PCB (110) on the PCB attachment plate;
pressing (S2) the PCB (110) to the PCB attachment plate (120), wherein the PCB aperture (111) is aligned with the ridge (122), and curing the first adhesive;
applying (S3) a second adhesive to the ridge (122) and arranging the quantum processor chip (101) on the ridge;
pressing (S4) the quantum processor chip (101) to the ridge (122) and curing the second adhesive; and
arranging (S5) wire bonds between respective first ends (113) of the transmission lines (112) of the PCB (110) and respective pads arranged on the quantum processor chip (101).
